(19) United States
(12) Patent Application Publication
(10) Pub. No.: US 2006/0138085 A1
(43) Pub. Date: Jun. 29, 2006

(54) Plasma etching method with reduced particles production

(76) Inventors: Chun-Hsien Chien, Sinjhuang City (TW); Chung-Ji Chen, Taipei City (TW)

Correspondence Address: J C PATENTS, INC., 4 VENTURE, SUITE 250, IRVINE, CA, 92618, US

(21) Appl. No.: 11/022,227

(22) Filed: Dec. 23, 2004

(51) Int. Cl. B44C 1/22; H01L 21/302; C23F 1/00

(52) U.S. Cl. 216/67; 438/706; 438/710; 216/41

(57) ABSTRACT

A plasma etching method, wherein less particles is produced, for forming trenches in a substrate is provided. The method includes performing a first etching step on a substrate using a first etching condition and then performing a second etching step on the substrate using a second etching condition. Between the first and the second etching step, a transition step is carried out in which the variation of each reaction chamber parameters is adjusted below a specific percentage, such as, 15%. By so doing, the number of particles is substantially reduced. An oxygen plasma-cleaning operation is also performed at a pressure between 40 mTorr to 80 mTorr inside the reaction chamber to reduce the number of defects.

### BACKGROUND OF THE INVENTION

1. Field of the Invention

The present invention relates to a plasma etching method. More particularly, the present invention relates to a plasma etching method with reduced particles production for forming a shallow trench isolation structure.

2. Description of the Related Art

In semiconductor fabrication, etching is mainly used for transferring patterns. Most etching operations are carried out alongside photolithographic processes. First, a photoresist layer is deposited over a substrate and then the photoresist layer is exposed to transfer a pattern on a photomask to the photoresist layer. Thereafter, the exposed photoresist layer is chemically developed to remove the unexposed photoresist material. Using the patterned photoresist layer as an etching mask, a wet etching or dry etching operation is carried out to remove a portion of the substrate. Finally, the patterned photoresist layer is removed so that a replica of the pattern on the photomask has been transferred to the substrate.

Most etching in semiconductor production involves either a wet etching or a dry etching operation. In dry etching, gaseous reactants inside a reaction chamber are first ionized or dissociated to produce plasma. Thereafter, the reactive ions within the plasma are next accelerated to a high speed before projecting onto a wafer. Through the interactions between the accelerated ions and the wafer, an etching reaction has been triggered. Thus, by adjusting the parameters for setting the etching conditions, one particular type of material can be selectively removed from the wafer form a variety of patterns.

One major advantage of dry etching is that the etching operation is anisotropic. Unlike the wet etching operation, there is no undercutting of materials after a dry etching operation. Consequently, a dry etching is preferred over a wet etching operation whenever a sharp profile (such as a deep trench) is demanded after an etching operation.

In a shallow trench isolation (STI) process, a dry etching technique is typically used to form a trench in a substrate. The conventional method of forming a STI structure includes the following steps. First, a pad oxide layer and a silicon nitride (Si₃N₄) mask layer are formed sequentially over a substrate. Thereafter, a photolithographic process is performed to define the location of the trench. Finally, a plasma etching operation is carried out to etch the silicon nitride mask, the pad oxide layer and the substrate and form a trench in the substrate.

In the aforementioned process of forming the trench in the substrate, at least two etching steps each having different etching parameters are used. Between the two etching steps, a stabling step is often introduced for adjusting the etching conditions. In a conventional stabling step, plasma production is directly shut down. The degree of environmental change in the reaction chamber induces the producing of particles. In the other word, the temperature inside the reaction chamber is high when the plasma production is turned on while the temperature inside the reaction chamber drops once the plasma production is stopped, some volatile gases produced by the previous plasma etching step may be cooled and then precipitate to form particles during the stabling step (no plasma production). FIGS. 1A and 1B are pictures showing some of the defects produced by a conventional plasma-etching method. As shown in FIG. 1A, particles 110 may form in the trench 120 when the temperature in the reaction chamber drops. Hence, the conductivity of circuit lines 130 and ultimately the electrical performance of the device may be affected.

Furthermore, an oxygen-plasma cleaning is frequently carried out after the etching operation. Typically, the oxygen plasma is capable of removing residues and pollutants coming from the reaction chamber, operators and the previous plasma-etching step in preparation for the next plasma-etching operation. However, as shown in FIG. 1B, defects 140 that may affect the conductivity of a circuit line 130 are still found on some of the trenches 120.

### SUMMARY OF THE INVENTION

Accordingly, an objective of the present invention is to provide a plasma-etching method with reduced particles production for forming a trench in a substrate. The plasma-etching method permits the adjustment of parameters including reaction chamber pressure, air flow rate, plasma power and reaction chamber temperature in a transition step between two etching steps without cutting off plasma production. And the variation of each parameter is adjusted below a specific for reducing particles produced.

An objective of the present invention is to provide a plasma-etching method, wherein less particles is produced, forming a trench in a substrate. The very last step of the plasma-etching method includes performing an oxygen-plasma cleaning inside a reaction chamber set to a pressure between 40 mTorr to 80 mTorr so that defects are eliminated.

To achieve these and other advantages and in accordance with the purpose of the invention, as embodied and broadly described herein, the invention provides a plasma-etching method. The plasma-etching method comprises performing a first etching step to etch a substrate under a first condition with a plurality of parameters, performing a transition step under a second condition with the parameters, wherein a variation between each parameters of the second condition from the corresponding parameters to the first condition is below 15%; and then performing a second etching step to etch the substrate under a third condition with the parameters, the variation of each parameter of the third condition from the corresponding parameter of the second condition is below 15%. The parameters such as the pressure of the reaction chamber, the gas flow rate, the plasma power and the temperature of the reaction chamber are adjusted, and the variation of each parameters are adjusted below a specific percentage for reducing particles produced.

The present invention also provides a plasma-etching method, wherein less particles is produced, for forming trenches in a substrate. The substrate has a masking layer and a patterned photoresist layer already formed thereon. The plasma-etching method comprises performing a first etching step to remove a portion of the masking layer using the patterned photoresist layer as a mask and performing a second etching step to remove a portion of the substrate using the masking layer as a mask. Between the first and the second etching step, a first transition step is carried out in which at least one of the parameters such as the pressure of the reaction chamber, the gas flow rate, the plasma power and the temperature of the reaction chamber is adjusted, and the variation of these parameters are adjusted below a specific percentage for providing a stable environment so that the particle production is reduced. In addition, an oxygen-plasma cleaning is performed inside a reaction chamber set to a pressure between 40 mTorr to 80 mTorr so that the number of defects is reduced.

According to the plasma-etching method of the present invention, the transition step comprises adjusting the variation of one or a combination of the parameters such as the pressure of the reaction chamber, the gas flow rate, the plasma power and the temperature of the reaction chamber below a ratio for providing a stable environment to reduce the particle production. After the second etching step, an oxygen-plasma cleaning is carried out with the reaction chamber adjusted to a value between 40 mTorr to 80 mTorr to reduce the number of defects.

According to the plasma-etching method of the present invention, the step of using the masking layer as a mask to remove a portion of the substrate in the second etching step includes the following sub-steps. First, a third etching process is performed to round off the top section of the trench. Thereafter, a fourth etching process is performed to increase the depth of the trench. Finally, a fifth etching process is performed to round off the bottom section of the trench.

According to the plasma-etching method of the present invention, a second transition step is carried out between the third and the fourth etching step and a third transition step is carried out between the fourth and the fifth etching step. In the second and the third transition step, at least one of the parameters including the reaction chamber pressure, the gas flow rate, the plasma power and the reaction chamber temperature is adjusted to reduce the number of particles. In the aforementioned transition steps, at least one of the parameters such as the pressure of the reaction chamber, the gas flow rate, the plasma power and the temperature of the reaction chamber is adjusted, and the variation of each parameters are adjusted below a specific percentage for providing a stable environment so that the particle production is reduced.

In the present invention, a transition step without a shutdown of plasma production instead of the conventional stabling step with a shutdown of plasma production is carried out between plasma etching steps. Since plasma production is continued in the transition step, the reaction chamber remains in a standby state while at least one of the parameters including the reaction chamber pressure, the gas flow rate, the plasma power and the reaction chamber temperature are adjusted below a specific percentage for providing a stable environment so that the particle production is reduced. Hence, the reaction chamber is prevented from cooling off to produce particles as a result of the shutdown of plasma production. In addition, an oxygen-plasma cleaning is performed after the plasma-etching step with the oxygen flow rate adjusted such that the reaction chamber pressure is raised to a value between 40 mTorr to 80 mTorr instead of the conventional reaction chamber pressure of just 15 mTorr. Consequently, most residues precipitated out from the plasma-etching process are removed and the possibility of producing defects is significantly reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A and 1B are pictures showing some of the defects produced by a conventional plasma-etching method.

FIG. 2 is a flow diagram showing the steps in a plasma etching process according to one preferred embodiment of the present invention.

FIG. 3 is a flow diagram showing the steps for producing a trench according to one preferred embodiment of the present invention.

FIGS. 4A through 4G are schematic cross-sectional views showing the steps for forming a trench according to one preferred embodiment of the present invention.

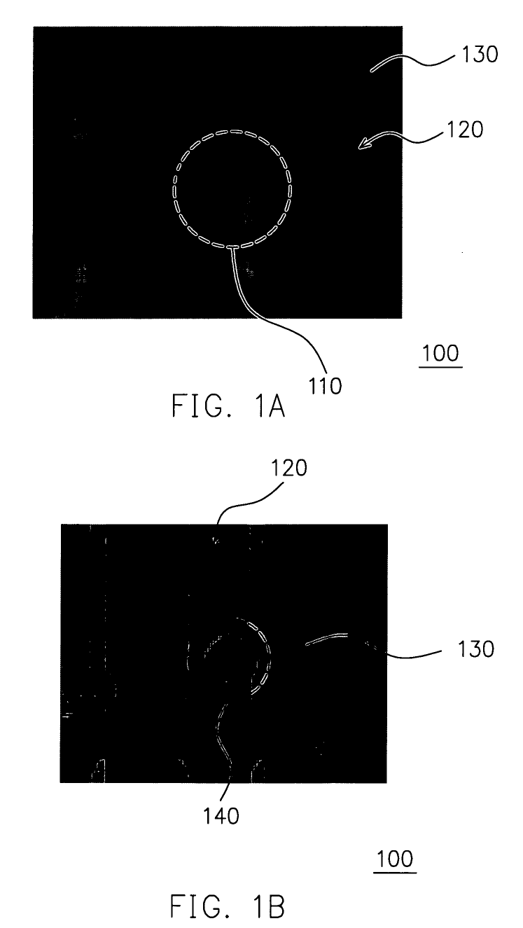

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

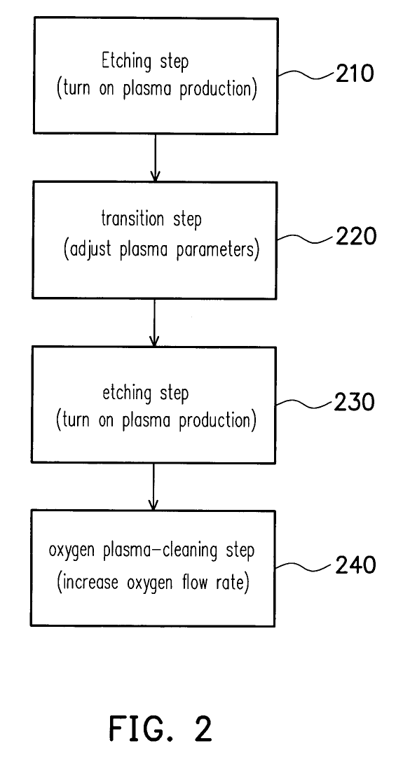

FIG. 2 is a flow diagram showing the steps in a plasma etching process according to one preferred embodiment of the present invention. As shown in FIG. 2, the plasma etching process of the present invention comprises at least a first etching step 210, a transition step 220, a second etching step 230 and an oxygen plasma-cleaning step 240. In the first etching step 210, a substrate is etched using a suitable etching condition. Before carrying out the next etching step 230, the transition step 220 is executed without turning off the plasma so that the reaction chamber is prevented from cooling off. Finally, the oxygen plasma-cleaning step 240 is carried out to remove any residues from the plasma etching steps.

As shown in FIG. 2, the gaseous reactants in the first etching step 210 and the second etching step 230 are ionized using plasma but set to different etching conditions so that the substrate are etched differently. Between the first etching step 210 and the second etching step 230, a transition step 220 is inserted. It should be noted that plasma production is maintained during the transition step 220. In the process, one or a combination of the parameters including the reaction chamber pressure, the gas flow rate, the plasma power and the reaction chamber temperature are adjusted. The variation of one or a combination of the parameters such as the pressure of the reaction chamber, the gas flow rate, the plasma power and the temperature of the reaction chamber are adjusted below a specific percentage between etching step 210, 230 and transition step 220 for providing a stable environment. Ultimately, the number of particles on the devices is substantially reduced.

As shown in FIG. 2, the adjustable plasma parameters in the transition step 220 includes the reaction chamber pressure condition, the gas flow rate, the plasma power and the reaction chamber temperature. The variation of each parameters are adjusted below a specific percentage, such as, 15%.

The reaction chamber pressure condition is directly related to the efficiency of the plasma etching because plasma etching is basically a process that utilizes the bombardment of plasma-ionized gaseous ions and the chemical reaction with non-mask protected material. A higher pressure inside the reaction chamber implies that more gaseous molecules are packed inside the reaction chamber to interfere with the ion bombarding process and lead to a drop in the etching efficiency.

The gas flow rate also directly affects the plasma etching efficiency because a higher flow rate means more gas molecules can be converted into plasma and vice versa. In fact, material etching only starts when a sufficient quantity of gases is converted into plasma.

The plasma power directly affects the build-up of plasma and the subsequent progress in the plasma etching operation.

The reaction chamber temperatures are the index of stable environment. In the plasma etching, the volatile gaseous products produced by the reaction between the plasma and the etching material may be precipitate somewhere inside the cooled reaction chamber. Such deposition may become a source of pollutant that affects subsequent plasma etching processes. Thus, it is important to adjust the reaction chamber temperature to inhibit needless deposition of volatile gases and maintain a certain degree of cleanliness inside the reaction chamber.

After performing the second etching step 230, an oxygen plasma-cleaning step 240 is carried out to remove residual compound produced by the plasma etching. In one embodiment, the oxygen flow rate in the oxygen plasma-cleaning step 240 is increased so that the reaction chamber pressure is raised to a value between 40 mTorr to 80 mTorr. Hence, pollutants from the reaction chamber, the operators or residual byproducts from the plasma etching are removed by reacting with the oxygen plasma. Since the raised pressure inside the reaction chamber in the oxygen plasma-cleaning step 240 can remove residual products from the plasma etching process, a major source of pollutants that may precipitate out to form defects is eliminated.

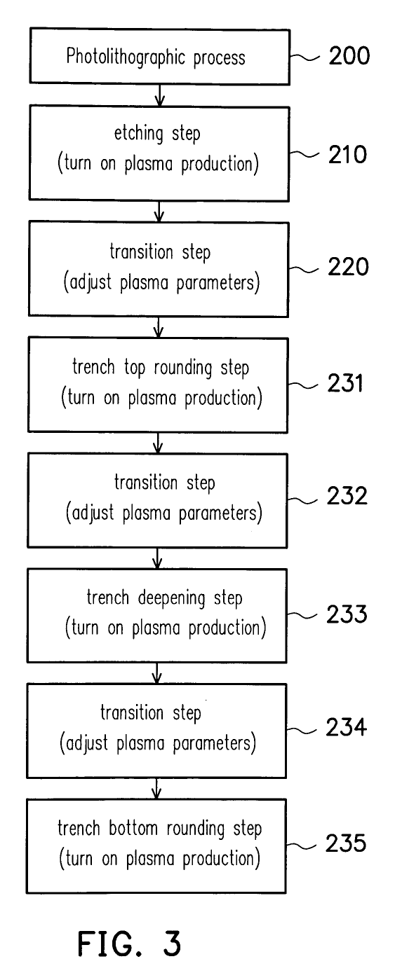

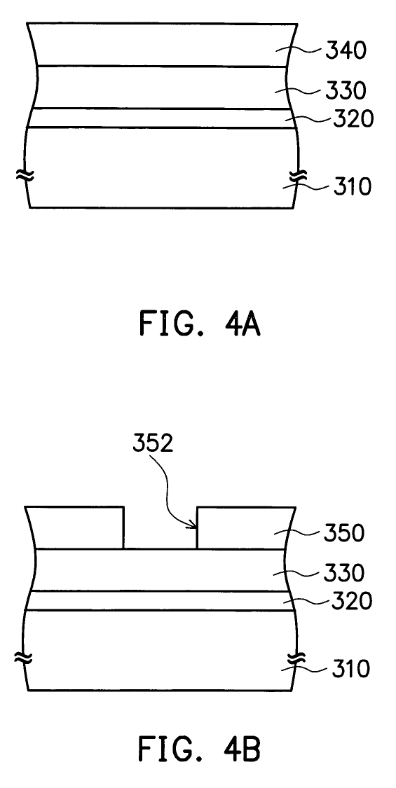

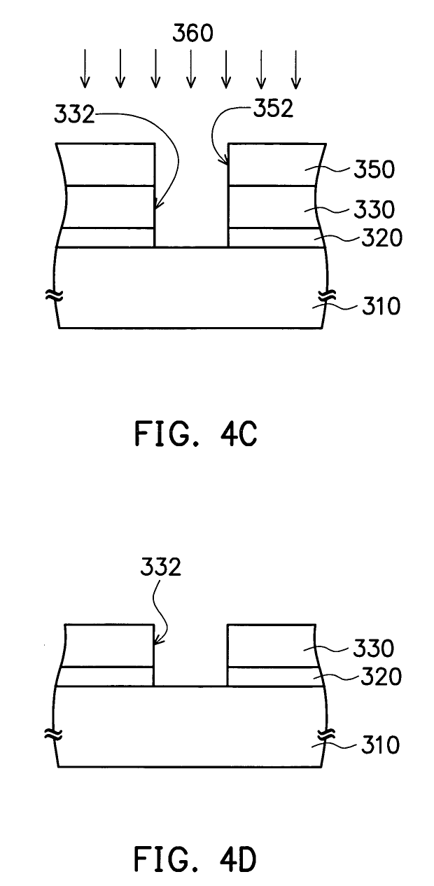

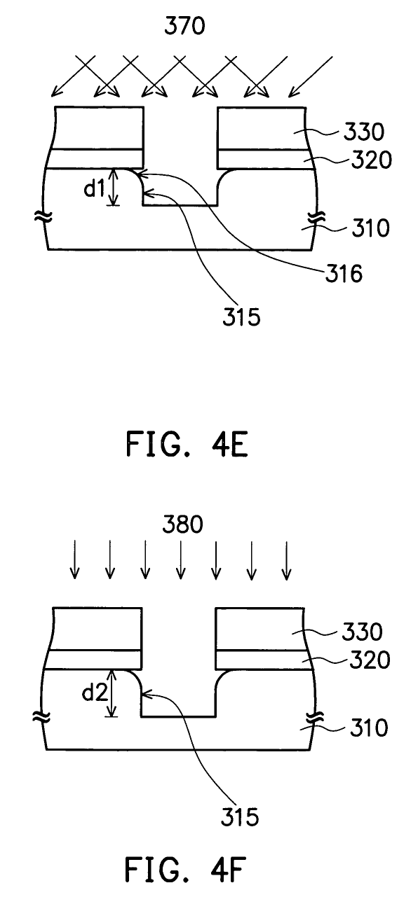

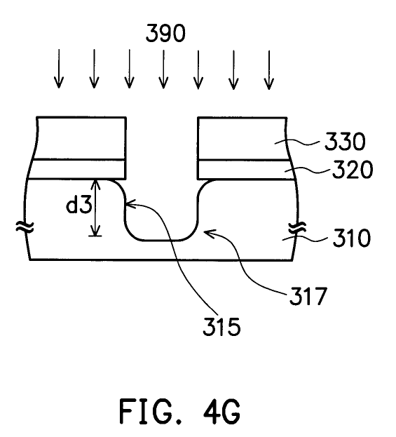

FIG. 3 is a flow diagram showing the steps for producing a trench according to one preferred embodiment of the present invention. Trench fabrication comprises a photolithographic process 200, an etching step 210, a first transition step 220, a trench top rounding step 231, a second transition step 232, a trench deepening step 233, a third transition step 234 and a trench bottom rounding step 235. FIGS. 4A through 4G are schematic cross-sectional views showing the steps for forming a trench according to one preferred embodiment of the present invention. As shown in FIGS. 3 and 4A, a substrate 310 having a pad oxide layer 320, a silicon nitride mask layer 330 and a photoresist layer 240 stacked thereon is provided as shown in step 200.

As shown in FIGS. 3 and 4B, the photoresist layer 340 is patterned to form a patterned photoresist layer 350 in step 200 by performing a photolithographic process. The patterned photoresist layer 350 has an opening 352 that exposes the silicon nitride mask layer 330. Thereafter, as shown in FIG. 3 and FIGS. 4C to 4G, trench-etching steps are carried out.

As shown in FIGS. 3 and 4C, a portion of the masking layer 330 and the pad oxide layer 320 are removed to form an opening 332 in the silicon nitride masking layer 330 by performing a plasma 360 etching process using the patterned photoresist layer 350 as a mask in step 210.

As shown in FIGS. 3 and 4D, the patterned photoresist layer 350 is removed in step 210. Thereafter, using the silicon nitride masking layer 330 as a hard mask, the trench-etching steps 231 to 235 for plasma-etching the substrate 310 are carried out through the opening 332 in the hard mask.

In one embodiment of the present invention as shown in FIG. 3, a transition step 220 is carried out between the etching step 210 and the trench top rounding step 231. In the transition step 220, at least one of the variations of the parameters including the reaction chamber pressure condition, the gas flow rate, the plasma power and the reaction chamber temperature is adjusted below a specific percentage, such as, 15%. Because the variation of each parameter is adjusted below a specific percentage, the degree of environmental change in the reaction chamber is reduced to inhibit particle production.

As shown in FIGS. 3 and 4E, using the silicon nitride masking layer 330 as a mask, the substrate 310 is etched using plasma 370 to form a trench 315. First, a trench top round off step 231 is carried out. In one embodiment, the ion bombarding angle of the plasma 370 can be changed or a suitable type of reactive plasma can be selected to increase the etching rate at the top section 316 of the trench 315 and hence round off the top section 316 of the trench 315.

In one embodiment of the present invention, another transition step 232 is carried out between the trench top rounding step 231 and the trench deepening step 233. In the transition step 232, at least one of the parameters including the reaction chamber pressure condition, the gas flow rate, the plasma power and the reaction chamber temperature is adjusted below a specific percentage, such as, 15%. Because the variation of each parameter is adjusted below a specific percentage, the degree of environmental change in the reaction chamber is reduced to inhibit particle production.

As shown in FIGS. 3 and 4F, a trench-deepening step 233 is carried out to increase the depth of the trench 315 using plasma 380. After the trench-deepening step 233, the depth of the trench 315 is increased from d1 shown in FIG. 4E to d2 shown in FIG. 4F. Because this step mainly serves to remove a portion of the substrate 310, the constituent gaseous plasma can be adjusted to increase the etching rate of the silicon substrate 310. Furthermore, the bombarding angle of ions can be set to a more vertical direction for increasing the downward dredging rate of the plasma.

In one embodiment of the present invention, another transition step 234 is carried out between the trench deepening step 233 and the trench bottom rounding step 235. In the transition step 234, at least one of the parameters including the reaction chamber pressure condition, the gas flow rate, the plasma power and the reaction chamber temperature is adjusted below a specific percentage, such as, 15%. Because the variation of each parameter is adjusted below a specific percentage, the degree of environmental change in the reaction chamber is reduced to inhibit particle production.

In FIGS. 3 and 4G, a trench bottom rounding step 235 is carried out using plasma 390. Through the ion bombardment of the plasma 390 and the re-deposition of volatile material created by the reaction between the plasma 390 and the substrate 310, the bottom section 317 of the trench is rounded. In the meantime, the depth d3 of the trench 315 is increased somewhat after the trench bottom rounding step 235.

After the trench etching steps, an oxygen plasma-cleaning step is carried out to remove any residual material produced in the plasma-etching steps. In the oxygen plasma-cleaning step, the oxygen flow rate is increased to raise the reaction chamber pressure to a value between 40 mTorr to 80 mTorr so that the residues and byproducts of the plasma etching process can be thoroughly removed. Thus, pollutants are inhibited from re-depositing on the devices on the wafer to form defects.

In the aforementioned transition steps, at least one of the parameters including the reaction chamber pressure, the gas flow rate, the plasma power and the reaction chamber temperature is adjusted to reduce the number of particles.

In summary, the plasma etching method of the present invention has at least the following advantages:

1. Plasma production is continued in the transition steps so that a constant temperature is maintained inside the reaction chamber. Thus, the re-deposition of volatile byproducts of the plasma etching operation to form particles due to sudden cooling is prevented.

2. The plasma etching state can be changed by adjust at least one of the reaction chamber parameters including the pressure, the gas flow rate, the plasma power and the temperature so that a higher plasma etching efficiency is obtained.

3. An oxygen plasma-cleaning step is carried out after the plasma etching steps. Furthermore, the oxygen flow rate in increased to raise the reaction chamber pressure to a value between 40 mTorr to 80 mTorr so that most residues and byproducts produced in the plasma etching process is removed. Hence, the number of defects is significantly reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A plasma etching method, wherein less particles is produced, comprising the steps of:
performing a first etching step to etch a substrate under a first condition with a plurality of parameters; and
performing a transition step under a second condition with the parameters, wherein a variation between each parameters of the second condition from the corresponding parameters to the first condition is below 15%; and
performing a second etching step to etch the substrate under a third condition with the parameters, the variation of each parameter of the third condition from the corresponding parameter of the second condition is below 15%.

2. The plasma etching method of claim 1, wherein the parameters comprise the reaction chamber pressure condition.

3. The plasma etching method of claim 1, wherein the parameters comprise the gas flow rate.

4. The plasma etching method of claim 1, wherein the parameters comprise the plasma power.

5. The plasma etching method of claim 1, wherein the parameters comprise the reaction chamber temperature.

6. The plasma etching method of claim 1, wherein after performing the second etching step further comprises carrying out an oxygen plasma-cleaning step such that the reaction chamber pressure is adjusted to a value between 40 mTorr to 80 mTorr.

7. A plasma etching method, wherein less particles is produced, for forming a trench in a substrate having a masking layer and a patterned photoresist layer already formed thereon, wherein the patterned photoresist layer has an opening that exposes the masking layer, the plasma etching method comprising the steps of:
performing a first etching step to remove a portion of the masking layer using the patterned photoresist layer as a mask;
performing a second etching step to remove a portion of the substrate and form a trench in the substrate using the masking layer as a mask, wherein a first transition step is carried out between the first etching step and the second etching step such that the variation of each reaction chamber parameters is adjusted below 15% to reduce particles; and
performing an oxygen plasma-cleaning step such that the reaction chamber pressure is adjusted to a value between 40 mTorr to 80 mTorr.

8. The plasma etching method of claim 7, wherein the parameters comprise the reaction chamber pressure condition.

9. The plasma etching method of claim 7, wherein the parameters comprise the gas flow rate.

10. The plasma etching method of claim 7, wherein the parameters comprise the plasma power.

11. The plasma etching method of claim 7, wherein the parameters comprise the reaction chamber temperature.

12. The plasma etching method of claim 7, wherein the step of performing the second etching step to remove a portion of the substrate and form a trench in the substrate using the masking layer as a mask further comprises:
performing a third etching step to round off the top section of the trench;
performing a fourth etching step to increase the depth of the trench; and
performing a fifth etching step to round off the bottom section of the trench;
wherein a second transition step is carried out between the third and the fourth etching step and a third transition step is carried out between the fourth and the fifth etching step such that the variation of each reaction chamber parameters is adjusted below a 15% to reduce particles.

13. The plasma etching method of claim 12, wherein the parameters comprise the reaction chamber pressure condition.

14. The plasma etching method of claim 12, wherein the parameters comprise the gas flow rate.

15. The plasma etching method of claim 12, wherein the parameters comprise the plasma power.

16. The plasma etching method of claim 12, wherein the parameters comprise the reaction chamber temperature.
